(19) United States
(12) Patent Application Publication
(10) Pub. No.: US 2025/0275334 A1
(43) Pub. Date: Aug. 28, 2025

(54) STRETCHABLE DISPLAY DEVICE

(71) Applicant: LG Display Co., Ltd., Seoul (KR)

(72) Inventors: Tae-Hyun KIM, Paju-si (KR); Sung-Joon MIN, Paju-si (KR); Yeon-Jun OH, Paju-si (KR); Do-Joong KIM, Paju-si (KR); Jun-Hyuk SONG, Paju-si (KR)

(73) Assignee: LG Display Co., Ltd., Seoul (KR)

(21) Appl. No.: 18/971,493

(22) Filed: Dec. 6, 2024

(30) Foreign Application Priority Data
Feb. 22, 2024 (KR) 10-2024-0025748

(51) Int. Cl. H10H 29/30; H10H 29/49

(52) U.S. Cl. CPC H10H 29/352; H10H 29/49

(57) ABSTRACT

A stretchable display device includes a display area including a first display area and a second display area adjacent to each other in a first direction; a plurality of rigid portions in the display area and spaced apart from each other in the first direction and a second direction; and a soft portion between adjacent rigid portions, among the plurality of rigid portions, in the first direction and the second direction, wherein the plurality of rigid portions include first, second, and third rigid portions, wherein the first rigid portion is provided in the first display area, and the second rigid portion is provided in the second display area, and wherein the third rigid portion is disposed between the first rigid portion and the second rigid portion and has a larger area than each of the first and second rigid portions.

### CROSS-REFERENCE TO RELATED APPLICATION

The present application claims priority to Korean Patent Application No. 10-2024-0025748, filed in the Republic of Korea on Feb. 22, 2024, the entire contents of which are hereby expressly incorporated by reference into the present application.

### BACKGROUND

### Field of the Disclosure

The present disclosure relates to a display device, and more particularly, to a stretchable display device.

### Discussion of the Background Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the size of the screen is increased, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid portion in which a pixel is disposed and a soft portion in which a connection line connecting the pixels is disposed. The rigid portion may not be stretched, and the soft portion may be stretched.

Accordingly, in order to secure stretching properties and repeated stretching reliability, a sufficient space for the soft portion is required, which limits the increase in the resolution of the stretchable display device.

### SUMMARY

Accordingly, an object of the present disclosure is to provide a stretchable display device that substantially obviates one or more of the limitations and disadvantages described above and associated with the background art.

Also, another object of the present disclosure is to provide a stretchable display device with high resolution.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other aspects of the present disclosure, as embodied and broadly described herein, a stretchable display device includes a display area including a first display area and a second display area adjacent to each other in a first direction; a plurality of rigid portions in the display area and spaced apart from each other in the first direction and a second direction; and a soft portion between adjacent rigid portions, among the plurality of rigid portions, in the first direction and the second direction, wherein the plurality of rigid portions include first, second, and third rigid portions, wherein the first rigid portion is provided in the first display area, and the second rigid portion is provided in the second display area, and wherein the third rigid portion is disposed between the first rigid portion and the second rigid portion and has a larger area than each of the first and second rigid portions.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure. In the drawings:

FIG. 1 is a schematic plan view of a stretchable display device according to an embodiment of the present disclosure;

FIG. 2 is a cross-sectional view corresponding to line I-I′ in FIG. 1;

FIG. 3 is a schematic plan view enlarging a part of a stretchable display device according to an embodiment of the present disclosure;

FIG. 4 is an equivalent circuit diagram for a sub-pixel of a stretchable display device according to an embodiment of the present disclosure;

FIG. 5 is a schematic cross-sectional view along line II-II′ in FIG. 3;

FIG. 6 is a schematic plan view of the stretchable display device according to an embodiment of the present disclosure in the folded state; and

FIG. 7 is a schematic cross-sectional view corresponding to line III-III′ and line IV-IV′ in FIG. 6.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art may unnecessarily obscure the gist of the present disclosure, the detailed description thereof may be omitted herein or may be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included.

Although the terms first, second, and the like may be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in a co-dependent relationship.

Hereinafter, example embodiments of the present disclosure will be described in detail with reference to accompanying drawings.

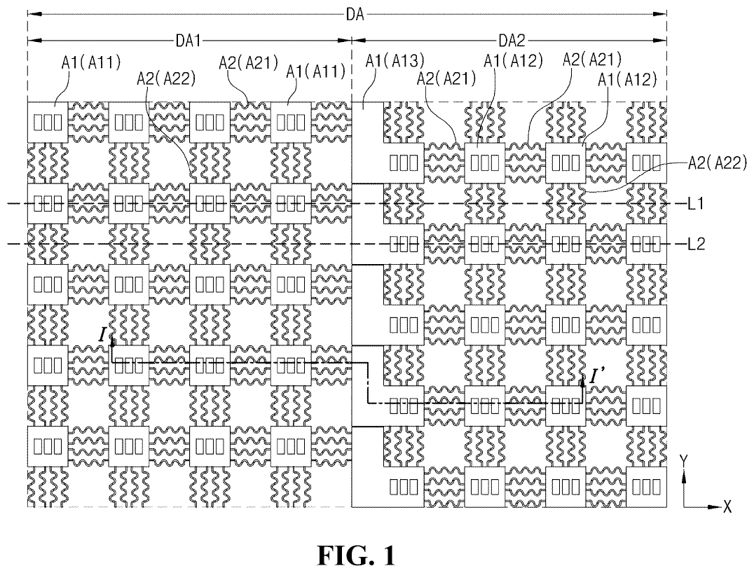

FIG. 1 is a schematic plan view of a stretchable display device according to an embodiment of the present disclosure.

In FIG. 1, a stretchable display device according to an embodiment of the present disclosure may include a rigid portion A1 and a soft portion A2 provided in a display area DA and may be stretched in a first direction X and/or a second direction. Here, the rigid portion A1 may not be stretched, and the soft portion A2 may be stretched.

The rigid portion A1 may be provided in the form of an island, and a plurality of rigid portions A1 may be disposed to be spaced apart from each other along the first direction X and the second direction Y. For example, the rigid portion A1 may have a polygonal shape. The rigid portions A1 may be arranged in a matrix form.

A pixel including a plurality of sub-pixels may be provided in the rigid portion A1. Each of the plurality of sub-pixels may include a light-emitting element, at least one thin film transistor, a plurality of signal lines, and a plurality of signal electrodes.

The soft portion A2 may be disposed between adjacent rigid portions A1 in each of the first direction X and the second direction Y. The soft portion A2 may include a horizontal soft portion A21 and a vertical soft portion A22. The horizontal soft portion A21 may extend substantially in the first direction X, and the vertical soft portion A22 may extend substantially in the second direction Y. Here, the horizontal soft portion A21 may be disposed between the adjacent rigid portions A1 in the first direction X, and the vertical soft portion A22 may be disposed between the adjacent rigid portions A1 in the second direction Y.

A stretchable line that is a connection line connecting the adjacent pixels may be provided in the soft portion A2. The stretchable line may include a plurality of voltage lines such as a gate line, a data line, a high potential line, a low potential line, an emission line, and a reference voltage line. The stretchable line may have at least one curved part.

The display area DA of the stretchable display device according to the embodiment of the present disclosure may include a first display area DA1 and a second display area DA2. The first display area DA1 and the second display area DA2 may be adjacent to each other in the first direction X.

A first rigid portion A11 may be provided in the first display area DA1, and a second rigid portion A12 may be provided in the second display area DA2.

Here, the first rigid portion A11 may be disposed on the same line as the second rigid portion A12 in the first direction X. That is, the first rigid portion A11 and the second rigid portion A12 may be disposed on different lines in the first direction X. Specifically, an imaginary straight line L1 passing through the centers of the first rigid portions A11 in the first direction X may not coincide with an imaginary straight line L2 passing through the centers of the second rigid portions A12 in the first direction X, and the imaginary straight lines L1 and L2 may be spaced apart from each other in the second direction Y.

In addition, a third rigid portion A13 may be further provided between the first rigid portion A11 and the second rigid portion A12. The third rigid portion A13 may be disposed in the second display area DA2.

The first rigid portion A11 and the second rigid portion A12 may have substantially the same shape, and the third rigid portion A13 may have a different shape from the first and second rigid portions A11 and A12. For example, the first and second rigid portions A11 and A12 may have a substantially square shape, and the third rigid portion A13 may have an L-like shape. However, embodiments of the present disclosure are not limited thereto, and the first, second, and third rigid portions A11, A12, and A13 may have various shapes.

Further, the area of the third rigid portion A13 may be greater than the area of each of the first and second rigid portions A11 and A12. In this case, the first and second rigid portions A11 and A12 may have the same shape.

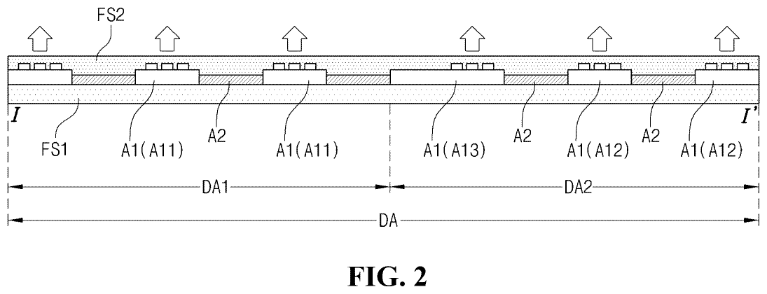

A cross-sectional structure of a stretchable display device according to the embodiment of the present disclosure will be described in detail with reference to FIG. 2.

FIG. 2 is a cross-sectional view corresponding to line I-I′ in FIG. 1.

In FIG. 2, the stretchable display device 100 according to the embodiment of the present disclosure may include a first flexible substrate FS1 and a second flexible substrate FS2. The rigid portions A1 and the soft portions A2 may be provided between the first flexible substrate FS1 and the second flexible substrate FS2. The first flexible substrate FS1 and the second flexible substrate FS2 may be attached to the rigid portions A1 and the soft portions A2 through a first adhesive layer and a second adhesive layer, respectively.

The first flexible substrate FS1 and the second flexible substrate FS2 may be formed of a soft matter or soft material with bending or stretching properties. For example, the first flexible substrate FS1 and the second flexible substrate FS2 may be formed of silicone rubber such as polydimethylsiloxane (PDMS), elastomer such as polyurethane (PU), or styrene butadiene block copolymer such as styrene butadiene styrene (SBS).

The first flexible substrate FS1 and the second flexible substrate FS2 may be formed of the same material. However, embodiments of the present disclosure are not limited thereto. In other embodiments, the first flexible substrate FS1 and the second flexible substrate FS2 may be formed of different materials.

The first flexible substrate FS1 and the second flexible substrate FS2 may have relatively low elastic modulus, that is, Young's modulus, and may have a relatively high ductile breaking rate. Here, the elastic modulus is a value representing the rate of deformation relative to the stress applied to an object. If the elastic modulus is relatively high, the hardness may be relatively high. In addition, the ductile breaking rate refers to the elongation rate at the point when the stretched object is broken or cracked.

For example, each of the first flexible substrate FS1 and the second flexible substrate FS2 may have the elastic modulus of several MPa to hundreds of MPa and the ductile breaking rate of about 100% or more. In addition, each of the first flexible substrate FS1 and the second flexible substrate FS2 may have a thickness of about 10 μm to about 1 mm. However, embodiments of the present disclosure are not limited thereto.

In addition, the first and second adhesive layers may be formed of an acryl-based, silicon-based, or urethane-based adhesive. For example, the first and second adhesive layers may be optically clear adhesive (OCA) that is formed and attached in the form of a film or optically clear resin (OCR) that is cured after applying a liquid material.

As described above, the display area DA may include the first display area DA1 and the second display area DA2. The plurality of first rigid portions A11 may be provided in the first display area DA1, the plurality of second rigid portions A12 may be provided in the second display area DA2, and the third rigid portion A13 may be provided between the first rigid portion A11 and the second rigid portion A12. The third rigid portion A13 may be disposed in the second display area DA2. However, embodiments of the present disclosure are not limited thereto. In other embodiments, the third rigid portion A13 may be disposed in the first display area DA1.

The soft portion A2 may be provided between the adjacent first, second, and third rigid portions A11, A12, and A13. Specifically, the soft portion A2 may be provided between the adjacent first rigid portions A11, between the adjacent second rigid portions A12, between the adjacent first and third rigid portions A11 and A13, and between the adjacent second and third rigid portions A12 and A13.

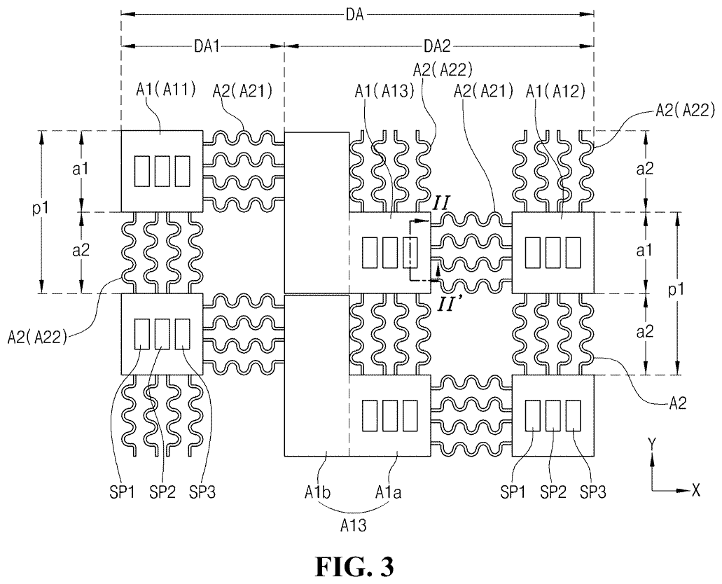

The configurations of the first, second, and third rigid portions A11, A12, and A13 will be described in detail with reference to FIG. 3.

FIG. 3 is a schematic plan view enlarging a part of a stretchable display device according to the embodiment of the present disclosure.

In FIG. 3, the stretchable display device according to the embodiment of the present disclosure may include the rigid portion A1 and the soft portion A2. The rigid portion A1 may include the first, second, and third rigid portions A11, A12, and A13, and the third rigid portion A13 may be disposed between the first and second rigid portions A11 and A12.

The pixel including the plurality of sub-pixels SP1, SP2, and SP3 may be provided in each of the first, second, and third rigid portions A11, A12, and A13. For example, first, second, and third sub-pixels SP1, SP2, and SP3 may be provided in each of the first, second, and third rigid portions A11, A12, and A13, and the first, second, and third sub-pixels SP1, SP2, and SP3 may be red, green, and blue sub-pixels, respectively. However, embodiments of the present disclosure are not limited thereto. In other embodiments, the first, second, and third sub-pixels SP1, SP2, and SP3 may be blue, green, and red sub-pixels, respectively.

Each of the first, second, and third sub-pixels SP1, SP2, and SP3 may include a light-emitting element, at least one thin film transistor, and at least one capacitor.

The soft portion A2 may be provided between the adjacent rigid portions A1 in each of the first direction X and the second direction Y, that is, between the adjacent first, second, and third rigid portions A11, A12, and A13 in each of the first direction X and the second direction Y. Specifically, the soft portion A2 may be provided between the adjacent first rigid portions A11 in each of the first direction X and the second direction Y, between the adjacent second rigid portions A12 in each of the first direction X and the second direction Y, between the adjacent third rigid portions A13 in the second direction Y, between the adjacent first and third rigid portions A11 and A13 in the first direction X, and between the adjacent second and third rigid portions A12 and A13 in the first direction X.

The soft portion A2 may include the horizontal soft portion A21 extending substantially in the first direction X and the vertical soft portion A22 extending substantially in the second direction Y.

The stretchable line may be provided in the soft portion A2. The stretchable line may have at least one curved part. For example, the stretchable line may have a wave structure and may include a plurality of wave shapes.

In the first direction X or the second direction Y, one rigid portion A1 and one soft portion A2 may form a unit, and a sum of a first length a1 of the rigid portion A1 and a second length a2 of the soft portion A2 may become a pitch p1 of one unit. Here, the first length a1 and the second length a2 may be equal to each other. That is, the first length a1 and the second length a2 may be ½ pitch, i.e., (p1)/2. However, embodiments of the present disclosure are not limited thereto. In other embodiments, the first length a1 may be smaller than the second length a2.

As described above, the first rigid portion A11 and the second rigid portion A12 in the first direction X may be disposed on different lines. In this case, the first rigid portion A11 and the second rigid portion A12 may be spaced apart by ½ pitch (p1)/2 in the second direction Y.

Meanwhile, the third rigid portion A13 may include an emission portion A1a and a connection portion A1b. The first, second, and third sub-pixels SP1, SP2, and SP3 may be provided in the emission portion A1a, and a plurality of signal lines may be provided in the connection portion A1b.

Here, the emission portion A1a of the third rigid portion A13 may have the same lengths of the first direction X and the second direction Y. On the other hand, the connection portion A1b of the third rigid portion A13 may have a length of the first direction X and a length of the second direction Y greater than the length of the first direction X, and the length of the second direction Y may be substantially equal to or smaller than the pitch p1.

The emission portion A1a of the third rigid portion A13 may have substantially the same shape as the first and second rigid portions A11 and A12. In addition, the emission portion A1a may have substantially the same configuration as the first and second rigid portions A11 and A12.

The emission portion A1a of the third rigid portion A13 may be disposed on the same line as the second rigid portion A12 in the first direction X and may be disposed on a different line from the first rigid portion A11.

On the other hand, the connection portion A1b of the third rigid portion A13 may have a length of the first direction X smaller than the first length a1 of the first and second rigid portions A11 and A12 and a length of the second direction Y greater than the first length a1 of the first and second rigid portions A11 and A12. In addition, the length of the second direction Y may be equal to or smaller than the pitch p1 and may be greater than ½ pitch (p1)/2. Accordingly, in the first direction X, the length of the connection portion A1b may be smaller than the length of the emission portion A1a, and in the second direction Y, the length of the connection portion A1b may be greater than the length of the emission portion A1a.

The third rigid portion A13 may have a substantially L-like shape. The connection portions A1b of the adjacent third rigid portions A13 in the second direction Y may be spaced apart from each other or may be in contact with each other. Preferably, the length of the connection portion A1b of the third rigid portion A13 in the second direction Y may be similar to the pitch p1. When the display device is not stretched in the second direction Y, the connection portions A1b of the adjacent third rigid portions A13 in the second direction Y may be in contact with each other, and when the display device is stretched in the second direction Y, the connection portions A1b of the adjacent third rigid portions A13 in the second direction Y may be spaced apart from each other. The area of the third rigid portion A13 may be greater than the area of the first and second rigid portions A11 and A12.

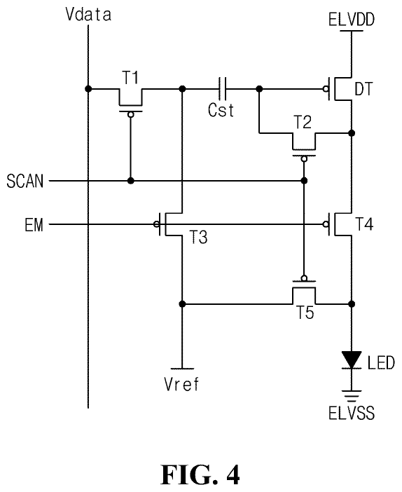

The configuration of the sub-pixel provided in the first, second, and third rigid portions A11, A12, and A13 may be described with reference to FIG. 4.

FIG. 4 is an equivalent circuit diagram for a sub-pixel of a stretchable display device according to an embodiment of the present disclosure.

In FIG. 4, one sub-pixel of the stretchable display device according to the embodiment of the present disclosure, that is, each of the first, second, and third sub-pixels SP1, SP2, and SP3 of FIG. 3 may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the gate signal SCAN and may be connected to the driving transistor DT. Specifically, a gate of the second transistor T2 may be connected to the scan signal SCAN. The source of the second transistor T2 may be connected to the first capacitor electrode of the storage capacitor Cst and the gate of the driving transistor DT. The drain of the second transistor T2 may be connected to the source of the driving transistor DT and the source of the fourth transistor T4.

The third transistor T3 may be switched according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched according to the gate signal SCAN and may be connected to the reference voltage Vref and the fourth transistor T4. Specifically, a gate of the fifth transistor T5 may be connected to the scan signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 4, as an example, each sub-pixel has a 6T1C structure including six transistors and one capacitor, but in other embodiments, each sub-pixel may have one of 2T1C, 4T1C, 5T1C, 3T2C, 4T2C, 5T2C, 6T2C, 7T1C, 7T2C, 8T1C, and 8T2C structures.

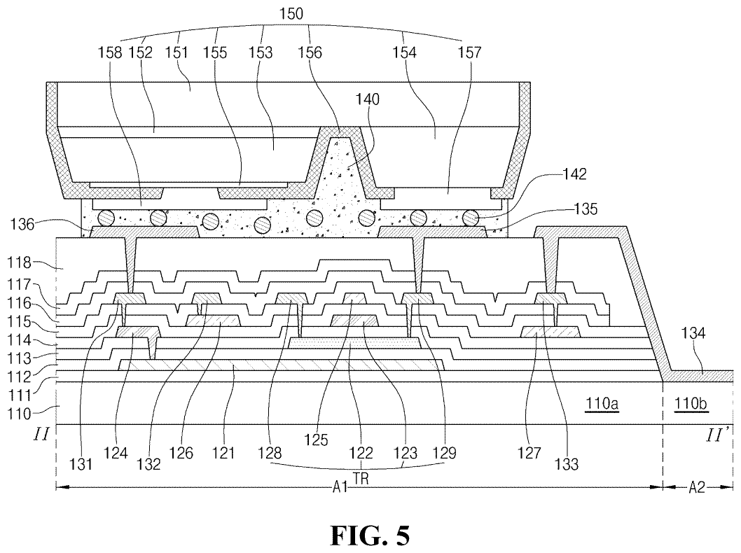

A cross-sectional structure of a stretchable display device according to an embodiment of the present disclosure will be described in detail with reference to FIG. 5.

FIG. 5 is a schematic cross-sectional view of a stretchable display device according to an embodiment of the present disclosure. FIG. 5 shows a cross-section corresponding to line II-II′ in FIG. 3.

In FIG. 5, the stretchable display device according to the embodiment of the present disclosure may include a base substrate 110 provided with the rigid portion A1 and the soft portion A2.

The base substrate 110 may include a first base portion 10a and a second base portion 110b. The first base portion 110a may be disposed to correspond to the rigid portion A1, and the second base portion 110b may be disposed to correspond to the soft portion A2.

The first base portion 110a may be provided in a plate shape in a display area and may serve to support and protect components of the plurality of sub-pixels SP1, SP2, and SP3. The first base portion 110a may be plural, and the plurality of first base portions 110a may be spaced apart from each other in the first direction X and the second direction Y.

The second base portion 110b may be provided between adjacent first base portions 110a in the first direction X and the second direction Y. The second base portion 110b may include at least one curved part and may serve to support and protect the stretchable line 134. The second base portion 110b may have substantially the same shape as the stretchable line 134. The first and second base portions 110a and 110b may be connected to each other and may be provided as one-body.

Meanwhile, the first flexible substrate FS1 of FIG. 2 may be provided under the base substrate 110. The first flexible substrate FS1 may be attached to the bottom surface of the base substrate 110 through the first adhesive layer.

The base substrate 110 may be formed of a rigid material having lower flexibility than the soft material of the first flexible substrate FS1. For example, the base substrate 110 may be formed of a polyimide (PI) resin or epoxy resin.

The base substrate 110 may have relatively high elastic modulus, and the elastic modulus of the base substrate 110 may be higher than the elastic modulus of the first flexible substrate FS1. For example, the elastic modulus of the base substrate 110 may be more than 1,000 times higher than the elastic modulus of the first flexible substrate FS1, but embodiments of the present disclosure are not limited thereto.

A first buffer layer 111 may be provided on the base substrate 110 as a first insulation layer. The first buffer layer 111 may block permeation of moisture or oxygen from the outside to protect the components of the plurality of sub-pixels SP1, SP2, and SP3.

The first buffer layer 111 may be formed as a single layer or multiple layers of an inorganic insulating material. The inorganic insulating material of the first buffer layer 111 may include silicon nitride (SiNx), silicon oxide (SiOx), or silicon oxynitride (SiON).

To prevent or reduce damage of the first buffer layer 111 such as cracks due to stretching, the first buffer layer 111 may be removed in the soft portion A2 to substantially correspond to the rigid portion A1, so that the first buffer layer 111 may be provided over the first base portion 110a of the base substrate 110 and may not be provided over the second base portion 110b.

In other embodiments, the first buffer layer 111 may be omitted.

A light shielding layer 121 may be provided on the first buffer layer 111 of the rigid portion A1. The light shielding layer 121 may be formed of a conductive material such as metal. For example, the light shielding layer 121 may be formed of at least one of aluminum (Al), copper (Cu), molybdenum (Mo), titanium (Ti), chromium (Cr), nickel (Ni), tungsten (W), or an alloy thereof. The light shielding layer 121 may have a single-layered structure or a multiple-layered structure.

A second buffer layer 112 may be provided on the light shielding layer 121 as a second insulation layer. The second buffer layer 112 may be formed as a single layer or multiple layers of an inorganic insulating material. The inorganic insulating material of the second buffer layer 112 may include silicon nitride (SiNx), silicon oxide (SiOx), or silicon oxynitride (SiON).

To prevent or reduce damage of the second buffer layer 112 such as cracks due to stretching, the second buffer layer 112 may be removed in the soft portion A2 to substantially correspond to the rigid portion A1. The second buffer layer 112 may be provided over the first base portion 110a of the base substrate 110 and may not be provided over the second base portion 110b.

A semiconductor layer 122 may be provided on the second buffer layer 112. The semiconductor layer 122 may overlap the light shielding layer 121, and the light shielding layer 121 may block light incident on the semiconductor layer 122 and prevent the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both ends of the semiconductor layer 122 may be doped with impurities.

A gate insulation layer 113 may be provided on the semiconductor layer 122 as a third insulation layer. The gate insulation layer 113 may be formed as a single layer or multiple layers of an inorganic insulating material. The inorganic insulating material of the gate insulation layer 113 may include silicon nitride (SiNx), silicon oxide (SiOx), or silicon oxynitride (SiON).

To prevent or reduce damage of the gate insulation layer 113 such as cracks due to stretching, the gate insulation layer 113 may be removed in the soft portion A2 to substantially correspond to the rigid portion A1. The gate insulation layer 113 may be provided over the first base portion 110a of the base substrate 110 and may not be provided over the second base portion 110b.

A gate electrode 123 and a first connection electrode 124 may be provided on the gate insulation layer 113.

The gate electrode 123 may overlap the semiconductor layer 122 and may be disposed to correspond to the central part of the semiconductor layer 122. Accordingly, the gate electrode 123 may also overlap the light shielding layer 121.

The first connection electrode 124 may be spaced apart from the semiconductor layer 122 and may overlap the light shielding layer 121. The first connection electrode 124 may be in contact with the light shielding layer 121 through a contact hole provided in the second buffer layer 112 and the gate insulation layer 113.

The gate electrode 123 and the first connection electrode 124 may be formed of a conductive material such as metal. For example, the gate electrode 123 and the first connection electrode 124 may be formed of at least one of aluminum (Al), copper (Cu), molybdenum (Mo), titanium (Ti), chromium (Cr), nickel (Ni), tungsten (W), or an alloy thereof. The gate electrode 123 and the first connection electrode 124 may have a single-layered structure or a multiple-layered structure.

A first interlayer insulation layer 114 may be provided on the gate electrode 123 and the first connection electrode 124 as a fourth insulation layer. The first interlayer insulation layer 114 may be formed as a single layer or multiple layers of an inorganic insulating material. The inorganic insulating material of the first interlayer insulation layer 114 may include silicon nitride (SiNx), silicon oxide (SiOx), or silicon oxynitride (SiON).

To prevent or reduce damage of the first interlayer insulation layer 114 such as cracks due to stretching, the first interlayer insulation layer 114 may be removed in the soft portion A2 to substantially correspond to the rigid portion A1. The first interlayer insulation layer 114 may be provided over the first base portion 110a of the base substrate 110 and may not be provided over the second base portion 110b.

An auxiliary electrode 125, an auxiliary line 126, and a pad electrode 127 may be provided on the first interlayer insulation layer 114. The auxiliary electrode 125 may overlap gate electrode 123, the semiconductor layer 122, and the light shielding layer 121. The auxiliary line 126 may overlap the light shielding layer 121 and may be spaced apart from the gate electrode 123, the semiconductor layer 122, and the first connection electrode 124. The pad electrode 127 may be spaced apart from the light shielding layer 121 and may be disposed close to an edge of the rigid portion A1 adjacent thereto.

The auxiliary electrode 125, the auxiliary line 126, and the pad electrode 127 may be formed of a conductive material such as metal. For example, the auxiliary electrode 125, the auxiliary line 126, and the pad electrode 127 may be formed of at least one of aluminum (Al), copper (Cu), molybdenum (Mo), titanium (Ti), chromium (Cr), nickel (Ni), tungsten (W), or an alloy thereof. The auxiliary electrode 125, the auxiliary line 126, and the pad electrode 127 may have a single-layered structure or a multiple-layered structure.

A second interlayer insulation layer 115 may be provided on the auxiliary electrode 125, the auxiliary line 126, and the pad electrode 127 as a fifth insulation layer. The second interlayer insulation layer 115 may be formed as a single layer or multiple layers of an inorganic insulating material. The inorganic insulating material of the second interlayer insulation layer 115 may include silicon nitride (SiNx), silicon oxide (SiOx), or silicon oxynitride (SiON).

To prevent or reduce damage of the second interlayer insulation layer 115 such as cracks due to stretching, the second interlayer insulation layer 115 may be removed in the soft portion A2 to substantially correspond to the rigid portion A1. The second interlayer insulation layer 115 may be provided over the first base portion 110a of the base substrate 110 and may not be provided over the second base portion 110b.

A source electrode 128 a drain electrode 129, a second connection electrode 131, and a power line 132 may be provided on the second interlayer insulation layer 115.

The source electrode 128 and the drain electrode 129 may be spaced apart from each other with the gate electrode 123 positioned therebetween and may be in contact with both ends of the semiconductor layer 122 through contact holes provided in the first and second interlayer insulation layers 114 and 115 and the gate insulation layer 113. The gate electrode 123 and the auxiliary electrode 125 may be disposed between the source electrode 128 and the drain electrode 129.

The semiconductor layer 122, the gate electrode 123, the source electrode 128, and the drain electrode 129 may constitute a thin film transistor TR.

The second connection electrode 131 may be spaced apart from the thin film transistor TR. The second connection electrode 131 may overlap the first connection electrode 124 and may be in contact with the first connection electrode 124 through a contact hole provided in the first and second interlayer insulation layers 114 and 115. In addition, the second connection electrode 131 may overlap the light shielding layer 121.

The power line 132 may be spaced apart from the thin film transistor TR. The power line 132 may overlap the auxiliary line 126 and may be in contact with the auxiliary line 126 through a contact hole formed in the second interlayer insulation layer 115.

For example, the power line 132 may be a line supplying the low potential voltage ELVSS. In this case, the power line 132 or the auxiliary line 126 may be connected to the light shielding layer 121. That is, the light shielding layer 121 may be supplied with the low potential voltage ELVSS.

The source electrode 128, the drain electrode 129, the second connection electrode 131, and the power line 132 may be formed of a conductive material such as metal. For example, the source electrode 128, the drain electrode 129, the second connection electrode 131, and the power line 132 may be formed of at least one of aluminum (Al), copper (Cu), molybdenum (Mo), titanium (Ti), chromium (Cr), nickel (Ni), tungsten (W), or an alloy thereof. The source electrode 128, the drain electrode 129, the second connection electrode 131, and the power line 132 may have a single-layered structure or a multiple-layered structure.

Next, a third interlayer insulation layer 116 may be provided on the source electrode 128, the drain electrode 129, the second connection electrode 131, and the power line 132 as a sixth insulation layer. The third interlayer insulation layer 116 may be formed as a single layer or multiple layers of an inorganic insulating material. The inorganic insulating material of the third interlayer insulation layer 116 may include silicon nitride (SiNx), silicon oxide (SiOx), or silicon oxynitride (SiON).

To prevent or reduce damage of the third interlayer insulation layer 116 such as cracks due to stretching, the third interlayer insulation layer 116 may be removed in the soft portion A2 to substantially correspond to the rigid portion A1. The third interlayer insulation layer 116 may be provided over the first base portion 110a of the base substrate 110 and may not be provided over the second base portion 110b.

Next, an auxiliary pad 133 may be provided on the third interlayer insulation layer 116. The auxiliary pad 133 may overlap the pad electrode 127 and may be in contact with the pad electrode 127 through a contact hole provided in the second and third interlayer insulation layers 115 and 116.

The auxiliary pad 133 may be formed of a conductive material such as metal. For example, the auxiliary pad 133 may be formed of at least one of aluminum (Al), copper (Cu), molybdenum (Mo), titanium (Ti), chromium (Cr), nickel (Ni), tungsten (W), or an alloy thereof. The auxiliary pad 133 may have a single-layered structure or a multiple-layered structure.

A passivation layer 117 may be provided on the auxiliary pad 133. The passivation layer 117 may be formed as a single layer or multiple layers of an inorganic insulating material. The inorganic insulating material of the passivation layer 117 may include silicon nitride (SiNx), silicon oxide (SiOx), or silicon oxynitride (SiON).

To prevent or reduce damage of the passivation layer 117 such as cracks due to stretching, the passivation layer 117 may be removed in the soft portion A2 to substantially correspond to the rigid portion A1. The passivation layer 117 may be provided over the first base portion 110a of the base substrate 110 and may not be provided over the second base portion 110b.

In this case, edges of the passivation layer 117 and the third interlayer insulation layer 116 of the rigid portion A1 adjacent to the soft portion A2 may be partially removed, thereby exposing a top surface of the second interlayer insulation layer 115.

The passivation layer 117 may be omitted.

A planarization layer 118 may be provided on the passivation layer 117. The planarization layer 118 may eliminate a step difference due to the layers thereunder and may have a substantially flat top surface. The planarization layer 118 may be formed of an organic insulating material such as photosensitive acrylic polymer (photo acryl).

The planarization layer 118 may be provided in the rigid portion A1 and may not be provided in the soft portion A2. Accordingly, the planarization layer 118 may be provided over the first base portion 110a of the base substrate 110 and may not be provided over the second base portion 110b.

In the rigid portion A1, the planarization layer 118 may be in contact with side surfaces of the third interlayer insulation layer 116 and the passivation layer 117 and be in contact with the exposed top surface of the second interlayer insulation layer 115.

A first electrode 135, a second electrode 136, and the stretchable line 134 may be provided on the planarization layer 118. The first electrode 135, the second electrode 136, and the stretchable line 134 may be formed of a conductive material such as metal. For example, the first electrode 135, the second electrode 136, and the stretchable line 134 may be formed of at least one of aluminum (Al), copper (Cu), molybdenum (Mo), titanium (Ti), chromium (Cr), nickel (Ni), tungsten (W), or an alloy thereof. The first electrode 135, the second electrode 136, and the stretchable line 134 may have a single-layered structure or a multiple-layered structure.

The first electrode 135 may overlap the drain electrode 129 and may be in contact with the drain electrode 129 through a contact hole provided in the planarization layer 118, the passivation layer 117, and the third interlayer insulation layer 116. The second electrode 136 may overlap the second connection electrode 131 and may be in contact with the second connection electrode 131 through a contact hole provided in the planarization layer 118, the passivation layer 117, and the third interlayer insulation layer 116.

An end of the stretchable line 134 may be disposed on the planarization layer 118 of the rigid portion A1. The end of the stretchable line 134 may overlap the auxiliary pad 133 and may be in contact with the auxiliary pad 133 through a contact hole provided in the planarization layer 118 and the passivation layer 117. The end of the stretchable line 134 may also overlap the pad electrode 127.

The stretchable line 134 may extend into and be provided in the soft portion A2. The stretchable line 134 may be in contact with top and side surfaces of the planarization layer 160 in the rigid portion A1 and may be in contact with a top surface of the second base portion 110b in the soft portion A2. The stretchable line 134 may be in contact with side surfaces of the first buffer layer 111, the second buffer layer 112, the gate insulation layer 113, the first interlayer insulation layer 114, and the second interlayer insulation layer 115.

Meanwhile, a bank layer may be further provided on the first electrode 135, the second electrode 136, and the stretchable line 134. The bank layer may expose at least parts of the first electrode 135 and the second electrode 136 and may cover the end of the stretchable line 134.

Next, an adhesive layer 140 may be provided on the first and second electrodes 135 and 136 of the rigid portion A1. The adhesive layer 140 may be an anisotropic conductive film (ACF) including an insulating base member and a plurality of conductive balls 142 dispersed in the insulating base member, among others.

When heat or pressure is applied to the adhesive layer 140, the conductive balls 142 may be electrically connected in an area where the heat or pressure is applied, so that the adhesive layer 140 may have a conductive property. In an area where the heat or pressure is not applied, the adhesive layer 140 may have an insulating property.

The light-emitting element 150 may be provided on the adhesive layer 140. The light-emitting element 150 may be provided in the form of a micro light-emitting diode chip (micro LED chip or uLED chip) including a p-type layer 151, an active layer 152, an n-type layer 153, a p-electrode 157, and an n-electrode 158. In addition, the light-emitting element 150 may further include a first ohmic layer 154, a second ohmic layer 155, and a protection layer 156.

Specifically, the first ohmic layer 154 and the p-electrode 157 may be sequentially provided on one side of a bottom surface of the p-type layer 151, and the active layer 152, the n-type layer 153, the second ohmic layer 155, and the n-electrode 158 may be spaced apart from the first ohmic layer 154 and sequentially provided on another side of the bottom surface of the p-type layer 151.

Here, the protection layer 156 may be provided between the first ohmic layer 154 and the p-electrode 157 and between the second ohmic layer 155 and the n-electrode 158. The p-electrode 157 may be in contact with the first ohmic layer 154 through a contact hole formed in the protection layer 156, and the n-electrode 158 may be in contact with the second ohmic layer 155 through a contact hole formed in the protection layer 156. The protection layer 156 may cover and be in contact with a side surface of the first ohmic layer 154 and may cover and be in contact with side surfaces of the active layer 152, the n-type layer 153, and the second ohmic layer 155. In addition, the protection layer 156 may be in contact with the bottom surface of the p-type layer 151 between the first ohmic layer 154 and the active layer 152.

The p-electrode 157 of the light-emitting element 150 may be in contact with the first electrode 135 through the conductive balls 142, and the n-electrode 158 may be in contact with the second electrode 136 through the conductive balls 142. Accordingly, the p-electrode 157 of the light-emitting layer 150 may be connected to the drain electrode 129 of the thin film transistor TR through the first electrode 135, and the n-electrode 158 may be connected to the low potential voltage ELVSS through the second electrode 136.

The light-emitting element 150 may have a flip-chip structure in which the p-electrode 157 and the n-electrode 158 are provided on the same side (for example, a side facing the base substrate 110) and light is emitted through a side opposite to the side provided with the p-electrode 157 and the n-electrode 158 (for example, a top surface of the p-type layer 151). However, embodiments of the present disclosure are not limited thereto.

Alternatively, the light-emitting element 150 may have a lateral structure in which the n-electrode and the p-electrode are provided on the same side and light is emitted through the same side provided with the n-electrode and the p-electrode or a vertical structure in which the n-electrode and the p-electrode are provided on opposite sides.

In addition, the light-emitting element 150 may emit light through the side facing the base substrate 110 as well as the side opposite to the side facing the base substrate 110. That is, the light-emitting element 150 may be a double-sided light-emitting diode.

Meanwhile, the light-emitting element 150 of FIG. 5 has been described as a structure of a general red light-emitting diode in which the first ohmic layer 154 and the p-type layer 151 are sequentially placed on the p-electrode 157 and the second ohmic layer 155, the n-type layer 153, the active layer 152, and the p-type layer 151 are sequentially placed on the n-electrode 158. Alternatively, the light-emitting element 150 of FIG. 5 may be a general green or blue light-emitting diode in which the first ohmic layer, the p-type layer, the active layer, and n-type layer are sequentially placed on the p-electrode and the second ohmic layer and the n-type layer are sequentially placed on the n-electrode 158, and in this case, the arrangement and connection of the element may be changed in order to match the first and second electrodes 135 and 136.

Here, the light-emitting element 150 may have a concave portion between the p-electrode 157 and the n-electrode 158. The adhesive layer 140 may be in contact with the protection layer 156 in the concave portion.

Next, the second flexible substrate FS2 of FIG. 2 may be provided on the light-emitting element 150 and the stretchable line 134. The second flexible substrate FS2 may be attached to the top surfaces of the light-emitting element 150 and the stretchable line 134 through the second adhesive layer.

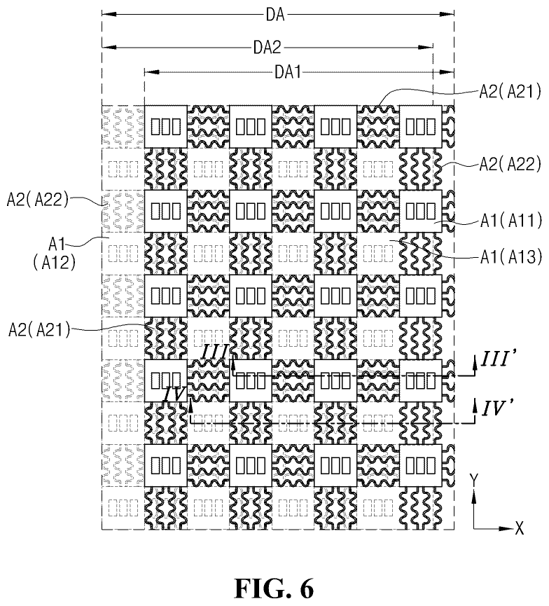

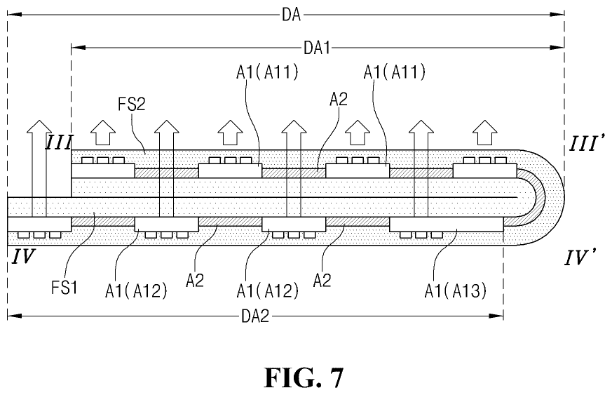

The stretchable display device according to the embodiment of the present disclosure can implement a relatively large screen in an unfolded state and a relatively high resolution in a folded state, and this will be described with reference to FIG. 6 and FIG. 7 together with FIG. 1 and FIG. 2.

FIG. 1 and FIG. 2 schematically show a stretchable display device according to the embodiment of the present disclosure in the unfolded state, and FIG. 6 and FIG. 7 schematically show the stretchable display device according to the embodiment of the present disclosure in the folded state. Here, FIG. 6 is a schematic plan view of the stretchable display device according to the embodiment of the present disclosure in the folded state, and FIG. 7 is a schematic cross-sectional view corresponding to line III-III′ and line IV-IV′ in FIG. 6.

As shown in FIG. 1 and FIG. 2, in the unfolded state, the first display area DA1 and the second display area DA2 may not overlap each other and may be disposed adjacent to each other in the first direction X.

Light from the light-emitting elements of the first, second, and third rigid portions A11, A12, and A13 may be emitted in one direction, for example, in an upward direction toward the second flexible substrate FS2 and may be output to the outside through the second flexible substrate FS2.

On the other hand, as shown in FIG. 6 and FIG. 7, in the folded state, the first display area DA1 and the second display area DA2 may overlap each other. In this case, the second display area DA2 may be disposed under the first display area DA1. That is, second display area DA2 may be folded into the rear surface of the first display area DA1 to thereby overlap each other. The portion of the first flexible substrate FS1 of the first display area DA1 and the portion of the first flexible substrate FS1 of the second display area DA2 may be disposed inside to face each other, and the portion of the second flexible substrate FS2 of the first display area DA1 and the portion of the second flexible substrate FS2 of the second display area DA2 may be exposed to the outside.

In FIG. 7, it is shown that the first rigid portion A11 overlaps the soft portion A2 of the second display area DA2 and the second rigid portion A12 overlaps the soft portion A2 of the first display area DA1. However, the first rigid portion A11 does not actually overlap the soft portion A2 of the second display area DA2, and the second rigid portion A12 does not actually overlap the soft portion A2 of the first display area DA1. In addition, it is shown that the emission portion A1a of the third rigid portion A13 overlaps the soft portion A2 of the first display area DA1 and the connection portion A1b overlaps the first rigid portion A11 of the first display area DA1. However, the emission portion A1a of the third rigid portion A13 does not actually overlap the soft portion A2 of the first display area DA1, and the connection portion A1b does not actually overlap the first rigid portion A11 of the first display area DA1 and does overlap the soft portion A2 of the first display area DA1.

In this case, the first rigid portion A11 of the first display area DA1 may be disposed between the adjacent soft portions A2 of the second display area DA2, the second rigid portion A12 of the second display area DA2 may be disposed between the adjacent soft portions A2 of the first display area DA1. Accordingly, the second rigid portion A12 may be disposed between the adjacent first rigid portions A11 in a third direction or a fourth direction crossing the first and second directions X and Y, and the first rigid portion A11 between the adjacent second rigid portions A12 in the third direction or the fourth direction. The first rigid portions A11 and the second rigid portions A12 may alternate in the third direction or the fourth direction.

In addition, the emission portion A1a of the third rigid portion A13 may be disposed between the adjacent soft portions A2 of the first display area DA1 and disposed between the adjacent first rigid portions A11 in the third direction or the fourth direction.

Meanwhile, the soft portions A2 of the first display area DA1 may overlap the soft portions A2 of the second display area DA2. Specifically, the horizontal soft portion A21 of the first display area DA1 may overlap the vertical soft portion A22 of the second display area DA2, and the vertical soft portion A22 of the first display area DA1 may overlap the horizontal soft portion A21 of the second display area DA2.

In the folded state, light from the light-emitting elements of the first rigid portions A11 may be emitted in the upward direction toward the second flexible substrate FS2 of the first display area DA1 and may be output to the outside through the second flexible substrate FS2.

On the other hand, in the folded state, light from the light-emitting elements of the second and third rigid portions A12 and A13 may be emitted in a downward direction toward the first flexible substrate FS1 of the second display area DA2 and may be output to the outside through the first flexible substrate FS1 of the second display area DA2 and the first flexible substrate FS1 and the second flexible substrate FS2 of the first display area DA1.

The light-emitting elements of the second and third rigid portions A12 and A13 may be double-sided light-emitting diodes, and the light-emitting elements of the first rigid portions A11 may be one-sided light-emitting diodes. However, embodiments of the present disclosure are not limited thereto.

In other embodiments, the light-emitting elements of the first rigid portions A11 may be double-sided light-emitting diodes, and the light-emitting elements of the second and third rigid portions A12 and A13 may be one-sided light-emitting diodes. Alternatively, all light-emitting elements of the first, second, and third rigid portions A11, A12, and A13 may be double-sided light-emitting diodes.

In addition, the up and down positions of the first and second display areas DA1 and DA2 may be reversed, and the first and second display areas DA1 and DA2 may be folded such that the portions of the second flexible substrate FS2 of the first and second display areas DA1 and DA2 may be disposed inside to face each other and the portions of the first flexible substrate FS1 of the first and second display areas DA1 and DA2 may be exposed to the outside.

In the folded state, light can be emitted in not only the first rigid portion A11 but also the second rigid portion A12 and the third rigid portion A13 between the adjacent first rigid portions A11 in the third direction or the fourth direction. Accordingly, the resolution in the folded state may be higher than the resolution in the unfolded state. For example, the resolution in the folded state may be twice the resolution in the unfolded state.

As such, in the stretchable display device, in the unfolded state, the relatively large screen may be implemented by displaying the image through the first and second display areas DA1 and DA2 horizontally adjacent to each other, and in the folded state, the relatively high resolution may be implemented by displaying the image through the first and second display areas DA1 and DA2 vertically overlapping each other.

In this case, the first and second rigid portions A11 and A12 of the first and second display areas DA1 and DA2 may be spaced apart by ½ pitch in the second direction Y and may have substantially the same configuration, and the emission portion A1a of the third rigid portion A13 may have substantially the same configuration as the second rigid portion A12. Accordingly, the stretchable display device according to the embodiment of the present disclosure can be manufactured using the existing panel process and transfer process.

In the stretchable display device of the present disclosure, the rigid portions of the first display area and the second display area may be spaced apart by ½ pitch, thereby implementing the relatively large screen in the unfolded state and implementing the relatively high resolution in the folded state.

In this case, since the rigid portions of the first display area and the second display area have substantially the same configuration, the stretchable display device can be manufactured using the existing panel process and transfer process, so that the process can be optimized or improved, and the production energy can be reduced.

It will be apparent to those skilled in the art that various modifications and variations can be made in the stretchable display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A stretchable display device, comprising:
a display area including a first display area and a second display area adjacent to each other in a first direction;
a plurality of rigid portions in the display area and spaced apart from each other in the first direction and a second direction; and
a soft portion between adjacent rigid portions, among the plurality of rigid portions, in the first direction and the second direction,
wherein the plurality of rigid portions include first, second, and third rigid portions,
wherein the first rigid portion is provided in the first display area, and the second rigid portion is provided in the second display area, and
wherein the third rigid portion is disposed between the first rigid portion and the second rigid portion and has a larger area than each of the first and second rigid portions.

2. The stretchable display device of claim 1, wherein the first rigid portion and the second rigid portion are disposed on different lines in the first direction.

3. The stretchable display device of claim 2, wherein one rigid portion and one soft portion form a unit, and the first rigid portion and the second rigid portion are spaced apart by ½ pitch of the unit.

4. The stretchable display device of claim 1, wherein the third rigid portion has an L-like shape.

5. The stretchable display device of claim 4, wherein the third rigid portion includes an emission portion and a connection portion, and the emission portion has a same shape and area as the first and second rigid portions.

6. The stretchable display device of claim 5, wherein the emission portion is disposed on a same line as the second rigid portion in the first direction and disposed on a different line from the first rigid portion in the first direction.

7. The stretchable display device of claim 5, wherein the connection portion has a longer length than the emission area in the second direction.

8. The stretchable display device of claim 5, wherein one rigid portion and one soft portion form a unit, and the connection portion has a length greater than ½ pitch of the unit and equal to or smaller than a pitch of the unit.

9. The stretchable display device of claim 5, wherein connection portions of adjacent third rigid portions in the second direction are spaced apart from each other.

10. The stretchable display device of claim 5, wherein:
with the stretchable display device not stretched, connection portions of adjacent third rigid portions in the second direction are in contact with each other; and
with the stretchable display device stretched, the connection portions of the adjacent third rigid portions in the second direction are spaced apart from each other.

11. The stretchable display device of claim 1, wherein in a folded state in which the first display area overlaps the second display area, the second rigid portion is disposed between adjacent first rigid portions in a third direction or a fourth direction crossing the first direction and the second direction.

12. The stretchable display device of claim 11, wherein a resolution in the folded state in which the first display area overlaps the second display area is greater than a resolution in an unfolded state in which the first display area does not overlap the second display area.

13. The stretchable display device of claim 11, wherein:
the soft portion includes a horizontal soft portion extending in the first direction and a vertical soft portion extending in the second direction; and
in the folded state in which the first display area overlaps the second display area, the horizontal soft portion of the first display area overlaps the vertical soft portion of the second display area, and the vertical soft portion of the first display area overlaps the horizontal soft portion of the second display area.

14. The stretchable display device of claim 1, further comprising:
a pixel provided in each of the plurality of rigid portions and including a plurality of sub-pixels; and
a stretchable line provided in the soft portion and connecting adjacent pixels.

15. The stretchable display device of claim 14, wherein:
each of a plurality of sub-pixels includes a light-emitting diode, at least one transistor, and at least one capacitor; and
the light-emitting diode provided in at least one of the first, second, and third rigid portions is a double-sided light-emitting diode.
